(19) United States
(12) Patent Application Publication
(10) Pub. No.: US 2010/0301182 A1
(43) Pub. Date: Dec. 2, 2010

(54) RETAINING DEVICE FOR HEAT-DISSIPATING APPARATUS

(75) Inventor: YI-JUN GUO, TAIPEI HSIEN (TW)

Correspondence Address: ROSENBERG, KLEIN & LEE, 3458 ELLICOTT CENTER DRIVE-SUITE 101, ELLICOTT CITY, MD, 21043, US

(73) Assignee: COOLER MASTER CO., LTD., TAIPEI HSIEN (TW)

(21) Appl. No.: 12/785,718

(22) Filed: May 24, 2010

(30) Foreign Application Priority Data
May 26, 2009 (TW) 98209259

(51) Int. Cl. H05K 7/02

(52) U.S. Cl. 248/309.1

(57) ABSTRACT

A retaining device for a heat-dissipating apparatus includes a first and second members, a retaining module and four retaining elements. The first member has at least one positioned slot formed at two ends thereof, a through hole formed at a centre thereof, and at least one locking pin adjacent to the through hole. The second member has at least one positioned slot formed at two ends thereof, a through hole formed at a centre thereof and at least one first fixing and second fixing holes formed around the through hole. The locking pin wedges in the first fixing hole. The retaining module is inserted in the through holes of the first and second members for fixing. The four retaining elements insert in the positioned slots of the first and the second members. The present invention can be adjustable in configuration and scale to fit for different mounting holes.

### BACKGROUND OF THE INVENTION

1. Field of the Invention

The present invention relates to a retaining device for a heat-dissipating apparatus, and more particular to a universal retaining device which can be adjustable to change its configuration and scale to fit different mounting holes. 2. Description of Related Art

Main boards from different CPU chip manufactories usually employ mounting holes of different specifications to meet heat-dissipating apparatus. The configuration of mounting holes could be divided into at least rectangle-pattern (as one specification) or square-pattern (as another specification). Furthermore, even the mounting holes of rectangle-pattern or square-pattern are further divided into different scales. To be compatible for such various mounting holes of different pattern, manufactories of heat-dissipating apparatus usually have to produce different retaining devices to attach heat-dissipating apparatus to main board of different specification, to perform the assembly of heat-dissipating apparatus.

However, it is difficult for the manufactories of heat-dissipating apparatus to determine the proper size and the actual pattern of mounting holes in advance, and what a main board that a heat-dissipating apparatus will be assembled thereon. Therefore, it is desirable that one usual package of heat-dissipating apparatus provided with different retaining devices for heat-dissipating apparatus of different specifications, and let consumers to select for assembling the heat-dissipating apparatus by themselves.

But such way of providing different retaining devices of various specifications at one time will raise the selling cost of heat-dissipating apparatus. Moreover, the other unused retaining devices of heat-dissipating apparatus will be discarded and results in unnecessary resources wasting.

Consequently, because of the technical limitations of described above, the applicant strives via real world experience and academic research to develop the present invention, which can effectively improve the limitations described above.

### SUMMARY OF THE INVENTION

The object of the present invention is to provide a retaining device for heat-dissipating apparatus that can change the specification pattern to fit for different mounting holes.

For achieving the object described above, a retaining device according to the present invention includes a first member, a second member, a retaining module and four retaining elements. Two ends of the first member have at least one positioned slot respectively. The first member has a through hole formed at a middle part thereof, and at least one locking pin equipped adjacent to the through hole.

Two ends of the second member have at least one positioned slot respectively. The second member has a through hole formed at a middle part thereof, at least one first fixing hole and at least one second fixing hole formed around a periphery of the through hole. The at least one locking pin of the first member is wedged in the at least one first fixing hole.

The retaining module is assembled through the through hole of the first member and the through hole of the second member, and clasps the first member and the second member in a predetermined position.

The four retaining elements are respectively assembled through the at least one positioned slot of the first member and the at least one positioned slot of the second member.

Through the above-mentioned assembly, the present invention can alter the specification pattern to achieve the purpose of being suitable for various mounting holes.

### BRIEF DESCRIPTION OF THE DRAWINGS

FIG. 1 is a perspective exploded view of the present invention;

FIG. 2 is a partial perspective view of the present invention;

FIG. 3 is a perspective view of the present invention assembled with a heat-dissipating apparatus;

FIG. 4 is a perspective view of the present invention being fixed in a rectangular configuration according to mounting holes of rectangle-pattern specification;

FIG. 5 is a top view of the present invention being fixed in a rectangular configuration according to the mounting holes of rectangle-pattern specification;

FIG. 6 is a perspective view according to mounting holes of square-pattern specification according to the present invention; and

FIG. 7 is a top view of the mounting holes of square-pattern specification according to the present invention.

### DETAILED DESCRIPTION OF PREFERRED EMBODIMENTS

The features and technology of the present invention can be further understood by reference to the following detailed description when taken in conjunction with the accompanying drawings, and the accompanying drawings are provided only for reference and illustration and not for limiting the present invention.

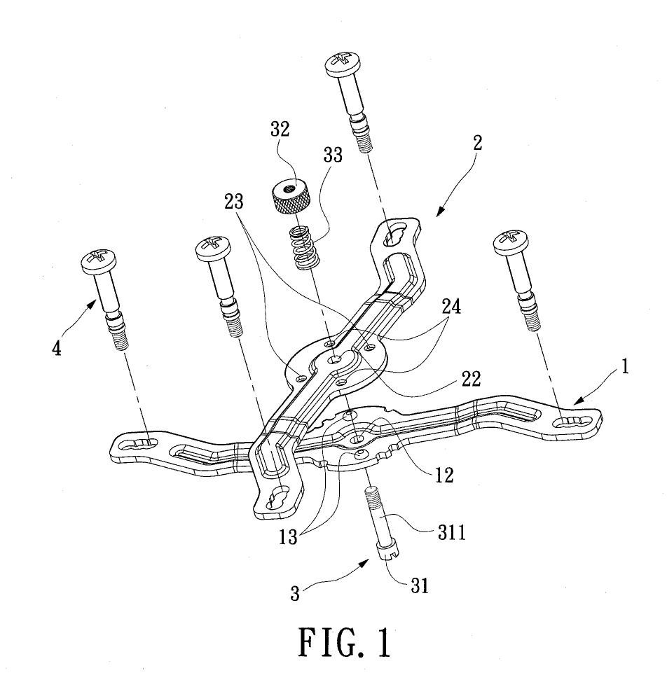

Please refer to FIG. 1 showing an embodiment of a retaining device of heat-dissipating apparatus according to the present invention, which includes a first member 1, a second member 2, a retaining module 3 and four retaining elements 4.

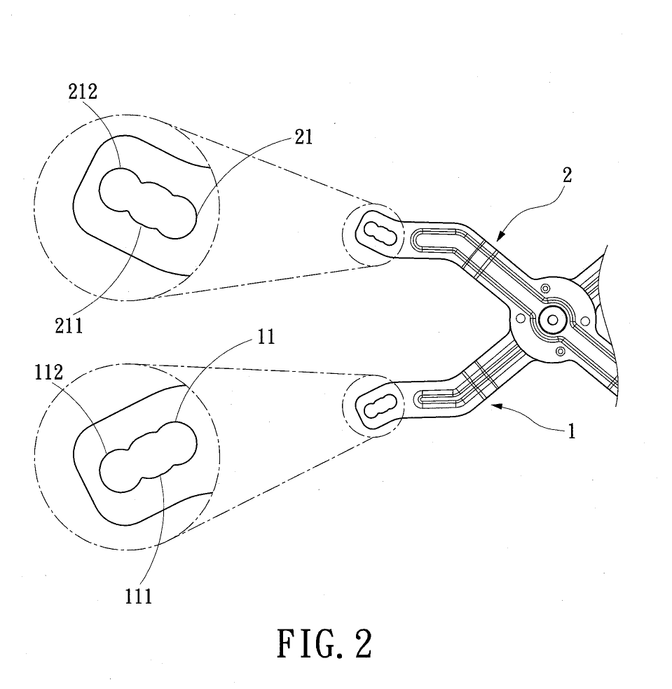

The first member 1, which is functioned as a retaining member, has two ends (in lateral direction) which respectively form a first positioned slot 11, a second positioned slot 111 and a third positioned slot 112 (also shown in FIG. 2). In this embodiment, the positioned slot is hole-shaped and communicated to each other, but it is not limited. For example, it could be a rectangular slot, or independent without communication. A middle part or a centre of the first member 1 has a through hole 12, and two locking pins 13 being symmetrical to each other which are disposed at a periphery of the through hole 12. The two locking pins 13 could be treated as a locking mechanism, which is disposed between the first and second retaining members 1, 2 to retain the angle between the retaining members.

The second member 2, which is functioned as another retaining member, has two ends (in lateral direction) which respectively form a first positioned slot 21, a second positioned slot 211 and a third positioned slot 212 (also shown in FIG. 2). A middle part or a centre of the second member 2 has a through hole 22. A middle part of the second member 2 has two first fixing holes 23, being symmetrical to each other, and two second fixing holes 24, being symmetrical to each other, which are formed at a periphery of the through hole 22. The two symmetrical locking pins 13 of the first member 1 are inserted into the two symmetrical first fixing holes 23 of the second member 2.

The retaining module 3 includes a bolt 31, a nut 32 and an elastic element 33. The bolt 31 is pivotally connected to the through hole 12 of the first member 1 and the through hole 22 of the second member 2, and has a section of screw-body 311 extended beyond the first member 1 and the second member 2. The nut 32 is screwed to the screw-body 311 exposed outside one side of the first member 1 and the second member 2. The elastic element 33 in this embodiment is a spring, which is disposed between the bolt 31 and the nut 32. The elastic element 33 is elastically pressed the first member 1 and the second member 2 in a fixed position. In other words, the retaining module 3 in this embodiment could be treated as a pivoting mechanism, which joins the first and second members 1, 2, at the center, so that providing angle adjustment between the first and second members 1, 2.

The four retaining elements 4 are illustrated and respectively inserted in the first positioned slot 11 of the first member 1 and the first positioned slot 21 of the second member 2 (also shown in FIG. 2).

Through the above-mentioned assembly, the present invention can alter its pattern to achieve the purpose of being suitable for various mounting holes.

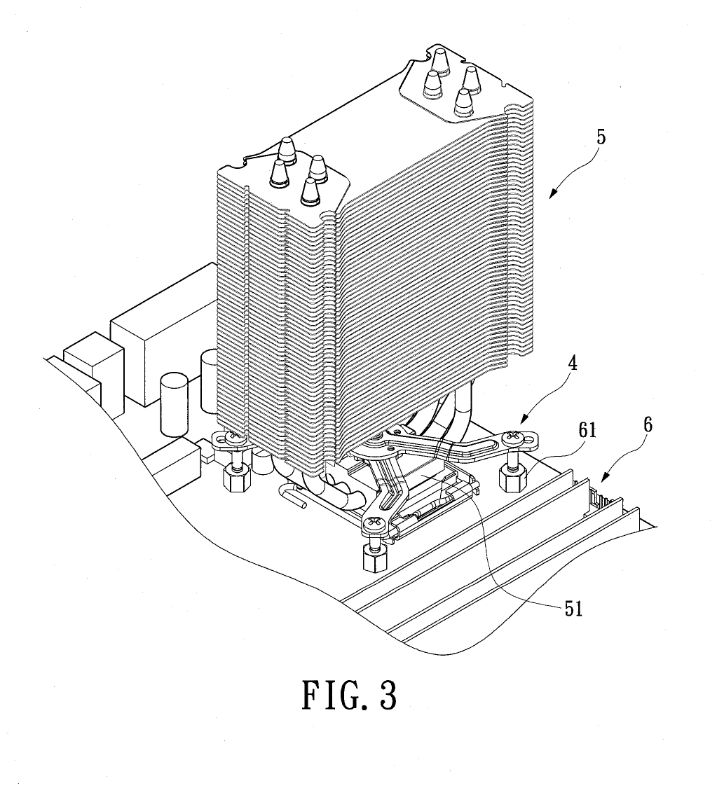

When practically use the present invention, firstly, it just need to put a base seat 51 of a heat-dissipating apparatus 5 under the present invention (as shown in FIG. 3). Then, use the four the retaining elements 4 of the present invention to fix in the mounting hole 61 of a main board 6. Thus, the heat-dissipating apparatus 5 could be pressed and retained by the present invention, and achieve the purpose of assembling the heat-dissipating apparatus 5.

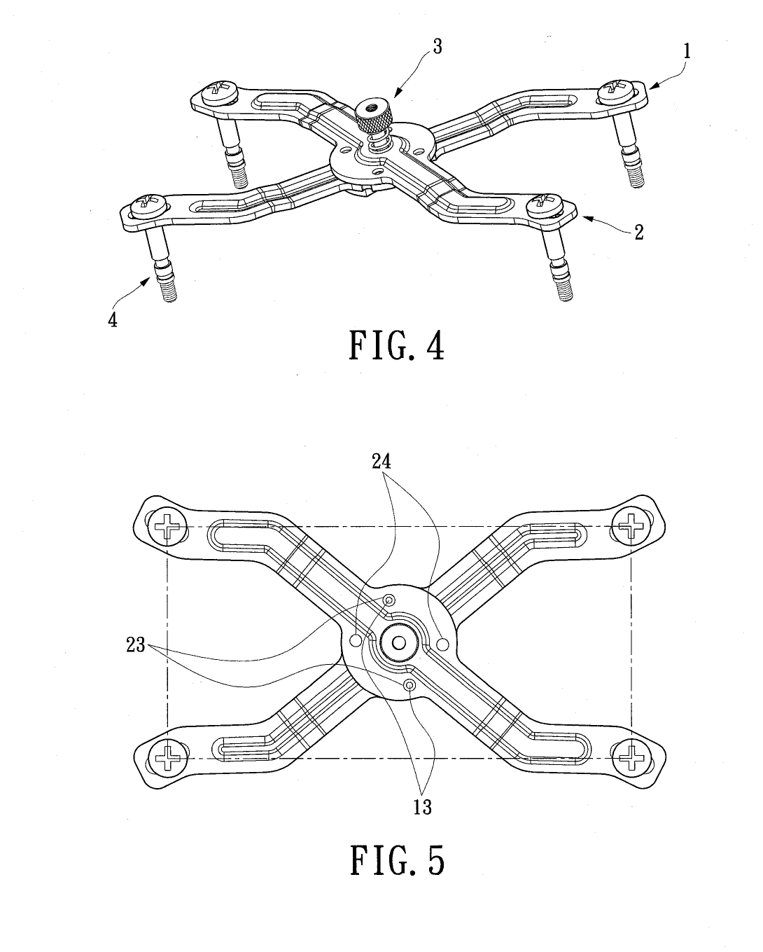

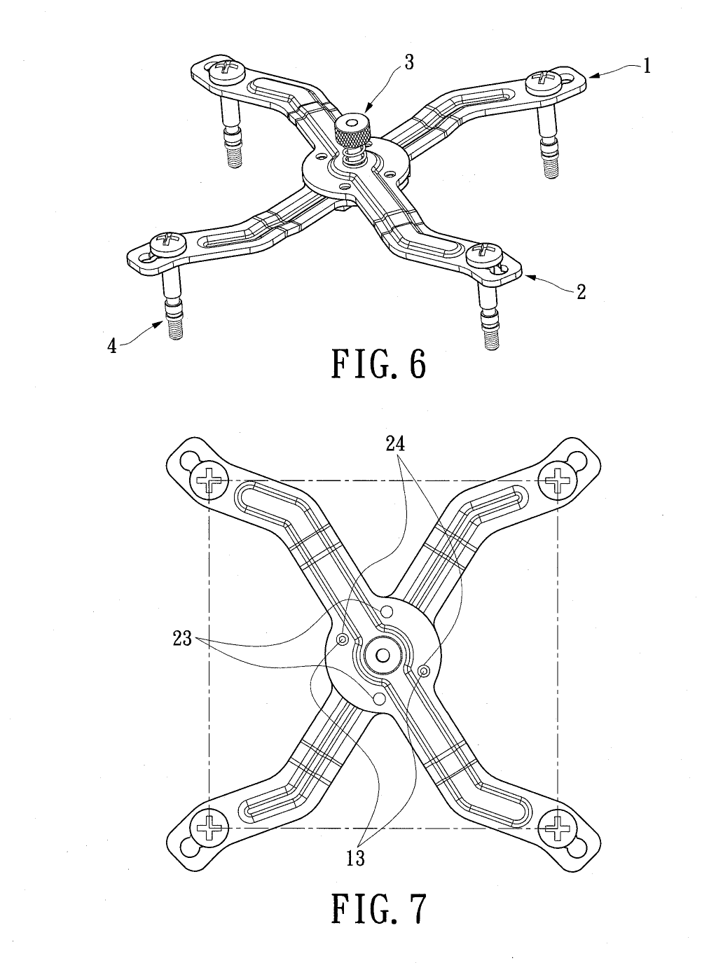

When the two symmetrical locking pins 13 are wedged with the two symmetrical first fixing holes 23 (as shown in FIGS. 4 and 5), the present invention is arranged as rectangular configuration which is suitable for the mounting holes of rectangular-pattern specification. If the present invention would be applied to the mounting holes of square-pattern specification, it only needs to wedge the two symmetrical locking pins 13 into the two symmetrical second fixing holes 24. Thus the present invention will be altered as square configuration for being suitable with the mounting holes of square-pattern specification (as shown in FIGS. 6 and 7).

Reference is made to FIGS. 2, 5 and 7. The present invention has further advantage because of the first positioned slots 11, 21, the second positioned slots 111, 211 and the third positioned slots 112, 212 formed on the first and second members 1, 2. The four retaining elements 4 could selectively insert in any one of the first positioned slots 11, 21, the second positioned slots 111, 211 and the third positioned slots 112, 212. The present invention thus can be suitable with the mounting holes of more different scales, including the square-pattern specification and the rectangular-pattern specification.

In another embodiment, the retaining element 4 of the present invention could be screwed-type bolts (as shown in FIG. 1) or barbed-type nails (not shown). The barbed-type nail is a nail formed with elastic barbs. After the barbed-type nail is inserted into the holes, the barbs will expand to make the nail clasped on the plate.

In a practical embodiment, the present invention could be formed with only one of the first positioned slot 11, the second positioned slot 111 and the third positioned slot 112 on the first member 1, and only one of the first positioned slot 21, the second positioned slot 211 and the third positioned slot 212 on the second member 2 (as shown in FIG. 1). Each side of the first and second members 1 and 2 only need one positioned slot, and then the present invention could be put into practice. It doesn't need to limit to one more positioned slot, which is stated here hereby.

In an alternative embodiment, the locking pins 13 of the present invention (as shown in FIG. 1), the corresponding first fixing holes 23 and the second fixing holes 24 could be equipped with a single one in practical, in which the invention may be put into practice. It doesn't need to limit to two in a symmetrical way, which is stated here hereby.

In an alternative embodiment, the retaining module 3 (as shown in FIG. 1) in practical would not be limited to the bolt 31, the nut 32 and the elastic element 33 disposed therebetween. It is also put into practice by using the bolt 31 and the nut 32 to clasp and retain the first member 1 and the second member 2, which is stated here hereby.

The efficacy and the characteristics of the present invention are:

While the present invention has been described in terms of what is presently considered to be the most practical and preferred embodiments, it is to be understood that the present invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A retaining device for a heat-dissipating apparatus, comprising:
a first member, having at least one positioned slot formed respectively at two ends thereof, a through hole formed at a middle part thereof, at least one locking pin located on the first member and around the through hole;
a second member, having at least one positioned slot formed respectively at two ends thereof, a through hole formed at a middle part thereof, at least one first fixing hole, and at least one second fixing hole around a periphery of the through hole of the second member, wherein the at least one locking pin of the first member is selectively wedged within the at least one first fixing hole;
a retaining module, assembled in the through hole of the first member and the through hole of the second member to clasp and retain the first member and the second member; and
a plurality of retaining elements, respectively inserted in the at least one positioned slot of the first member and the at least one positioned slot of the second member.

2. The retaining device for a heat-dissipating apparatus of claim 1, wherein the retaining module includes a bolt and a nut, the bolt is pivotally connected to the through hole of the first member and the through hole of the second member, wherein the bolt has a section of screw-body exposed outside the first and second members, and the nut is screwed to the exposed screw-body.

3. The retaining device for a heat-dissipating apparatus of claim 2, wherein the retaining module further comprises an elastic element, the elastic element is disposed between the bolt and the nut.

4. The retaining device for a heat-dissipating apparatus of claim 1, wherein the at least one locking pin of the first member is selectively wedged in the at least one second fixing hole of the second member.

5. The retaining device for a heat-dissipating apparatus of claim 1, wherein the four retaining elements are bolts.

6. The retaining device for a heat-dissipating apparatus of claim 1, wherein the four retaining elements are barbed nails.

7. A universal retaining device, comprising:
a first retaining member, having two ends and a center,
wherein each end of the first retaining member has a receiving slot;
a second retaining member, having two ends and a centre,
wherein each end of the first and the second retaining member has a receiving slot;
a pivoting mechanism, joining the first and second retaining members at the centre, thereby providing angle adjustment between the first and the second retaining members; and
a locking mechanism disposed between the first and second retaining members to retain an angle between the first and the second retaining members.

8. The retaining device of claim 7, wherein the pivoting mechanism comprises a bolt and a nut.

9. The retaining device of claim 8, wherein the pivoting mechanism further comprises an elastic element between the bolt and the nut.

10. The retaining device of claim 7, wherein the locking mechanism comprises a locking pin.
